(19) United States
(12) Patent Application Publication
(10) Pub. No.: US 2026/0165148 A1
(43) Pub. Date: Jun. 11, 2026

(54) FAN-OUT WAFER-LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/178,882

(22) Filed: Apr. 15, 2025

(30) Foreign Application Priority Data
Apr. 16, 2024 (TW) 113114154

(51) Int. Cl. H10W 70/09

(52) U.S. Cl. CPC H10W 70/09

(57) ABSTRACT

A fan-out wafer level packaging (FOWLP) unit which includes a substrate, a die, a first dielectric layer, a second dielectric layer, a plurality of conductive circuits, and an outer protective layer is provided. The conductive circuit is formed by metal paste filled in a plurality of first slots at the first dielectric layer and a plurality of second slots on the second dielectric layer. One end of the conductive circuit is electrically connected with a plurality of die pads of the die while the other end forms a bonding pad in respective openings of the outer protective layer and the bonding pad is exposed. At least one of the bonding pads is located around a chip area on a second surface of the die to form the FOWLP unit. The die is electrically connected to the outside through the die pads, the conductive circuits, and the bonding pads.

### CROSS-REFERENCE TO RELATED APPLICATIONS

This non-provisional application claims priority under 35 U.S.C. § 119(a) on Patent Application No(s). 113114154 filed in Taiwan, R.O.C. on Apr. 16, 2024, the entire contents of which are hereby incorporated by reference.

### BACKGROUND OF THE INVENTION

The present invention relates to a chip package unit, especially to a fan-out wafer-level packaging (FOWLP) unit.

Packaging technology with features of compact design, high efficiency and reliability is a trend in semiconductor industry. In the semiconductor packaging, Fan-Out Wafer Level Packaging (FOWLP) is a packaging technology available now. In advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is formed around the die in a more distributed manner. Thereby design space and reliability of the respective conductive circuits are effectively improved. Yet how to keep balance between the electrical extension in the XY plane and interconnections of the conductive circuits and the compact design to a certain degree. The most critical point is the manufacturing of the respective conductive circuits in the RDL. However, the formation of the respective conductive circuits in the RDL of the FOWLP technology available now is by chemical plating or electroplating. Thus not only cost for materials and manufacturing is high, the manufacturing process is also not environmental friendly.

### SUMMARY OF THE INVENTION

Therefore, it is a primary object of the present invention to provide a fan-out wafer level packaging (FOWLP) unit which includes a substrate, a die, a first dielectric layer, a second dielectric layer, a plurality of conductive circuits, and an outer protective layer. Each of the conductive circuits is formed by metal paste filled in a plurality of first slots arranged at the first dielectric layer and a plurality of second slots disposed on the second dielectric layer. One end of the conductive circuit is electrically connected with a plurality of die pads of the die while the other end of the respective conductive circuits is exposed through a plurality of openings of the outer protective layer and forming a bonding pad in the openings correspondingly. At least one of the bonding pads is located around a chip area on a second surface of the die to form the FOWLP unit. The die is electrically connected to the outside through the respective die pads, the respective conductive circuits, and the respective bonding pads. Thereby the problems of the fan-out level packaging technology available now generated during manufacturing of the respective conductive circuits including higher manufacturing cost and less environmental benefit can be solved effectively.

In order to achieve the above object, a fan-out wafer-level packaging (FOWLP) unit according to the present invention is provided. The FOWLP unit includes a substrate, a die, a first dielectric layer, a second dielectric layer, a plurality of conductive circuits, and an outer protective layer. The die is cut from a wafer and provided with a first surface and a second surface opposite to each other. The first surface of the die is fixed on the substrate while the second surface of the die is provided with a plurality of die pads. A horizontal chip area of the second surface is defined as a chip area. The first dielectric layer is mounted to the substrate and the second surface of the die and provided with a plurality of first slots extending in a horizontal direction. The respective die pads of the die are exposed through the respective first slots. The second dielectric layer is disposed over the first dielectric layer and provided with a plurality of second slots extending in a horizontal direction. The respective second slots are communicating with the respective first slots. The respective conductive circuits are formed by a metal paste filled in the respective first slots located at the first dielectric layer and the respective second slots located at the second dielectric layer. The respective conductive circuits are electrically connected with the respective die pads of the die. The outer protective layer is arranged over the second dielectric layer and provided with a plurality of openings. At least one of the openings is located around the chip area on the second surface of the die. Each of the respective conductive circuits is exposed through the corresponding opening and forming a bonding pad in the corresponding opening. The die is electrically connected to the outside through the respective die pads, the respective conductive circuits, and the respective bonding pads around the chip area on the second surface of the die. Thereby the FOWLP unit is formed.

A method of manufacturing the fan-out wafer-level packaging (FOWLP) unit according to the present invention includes the following steps. Step S1: providing a substrate. Step S2: arranging a plurality of dies cut from at least one wafer on the substrate and the dies are spaced apart from one another. Each of the dies includes a first surface and a second surface opposite to the first surface. The first surface of the die is arranged at the substrate while the second surface of the die is provided with a plurality of die pads. A horizontal chip area of the second surface is defined as a chip area. Step S3: paving a first dielectric layer over the substrate and the second surface of the respective dies. Step S4: forming a plurality of first slots extending horizontally on the first dielectric layer and exposing the respective die pads of the respective dies through the respective first slots. Step S5: arranging a second dielectric layer over the first dielectric layer. Step S6: forming a plurality of second slots extending horizontally on the second dielectric layer and the respective second slots communicating with the respective first slots. Step S7: filling a metal paste into the respective first slots and the respective second slots and a level of the metal paste is higher than a surface of the second dielectric layer. Step S8: grinding the metal paste with the level higher than the surface of the second dielectric layer to make a surface of the metal paste flush with the surface of the second dielectric layer and form a plurality of conductive circuits. Step S9: covering the second dielectric layer with an outer protective layer. Step S10: forming a plurality of openings on the outer protective layer and at least one of the openings is formed around the chip area on the second surface of the die so that the respective conductive circuits are exposed through the respective openings to form a bonding pad in each of the openings. Step S11: performing cutting to form a plurality of fan-out wafer-level packaging (FOWLP) units 1.

Preferably, the substrate includes silicon (Si) substrate, glass substrate, and ceramic substrate.

Preferably, the metal paste includes silver paste, nano-scale silver paste, copper paste, and nano-scale copper paste.

Preferably, the first surface of the die is fixed and arranged on the substrate by a die attach film (DAF).

Preferably, each of the openings is provided with a solder ball which is electrically connected with the bonding pad in the opening. Thus the FOWLP unit can be electrically connected to and disposed on a printed circuit board (PCB) by the respective solder balls.

### BRIEF DESCRIPTION OF THE DRAWINGS

FIG. 1 is a side sectional view showing a fan-out wafer level packaging unit disposed on a printed circuit board of an embodiment according to the present invention;

FIG. 2 is a side sectional view showing a die arranged at a substrate of an embodiment according to the present invention;

FIG. 3 is a side sectional view showing a first dielectric layer disposed on a substrate and a second surface of a die of an embodiment according to the present invention;

FIG. 4 is a side sectional view showing a second dielectric layer disposed on a first dielectric layer of an embodiment according to the present invention;

FIG. 5 is a side sectional view showing a first slot and a second slot both filled with metal paste of an embodiment according to the present invention;

FIG. 6 is a side sectional view showing grinding of the metal paste with a level higher than a surface of a second dielectric layer in the embodiment in FIG. 5 according to the present invention;

FIG. 7 is a side sectional view showing a plurality of openings formed on an outer protective layer of an embodiment according to the present invention;

FIG. 8 is a side sectional view of a fan-out wafer-level packaging (FOWLP) unit of an embodiment according to the present invention.

### DETAILED DESCRIPTION OF THE PREFERRED EMBODIMENT

In order to learn structure and technical features of the present invention, please refer to the following descriptions and related figures which are only used to explain relationship and functions of respective components of the present invention and sizes of the respective components are not drawn to real scale, and not intended to limit the scope of the present invention.

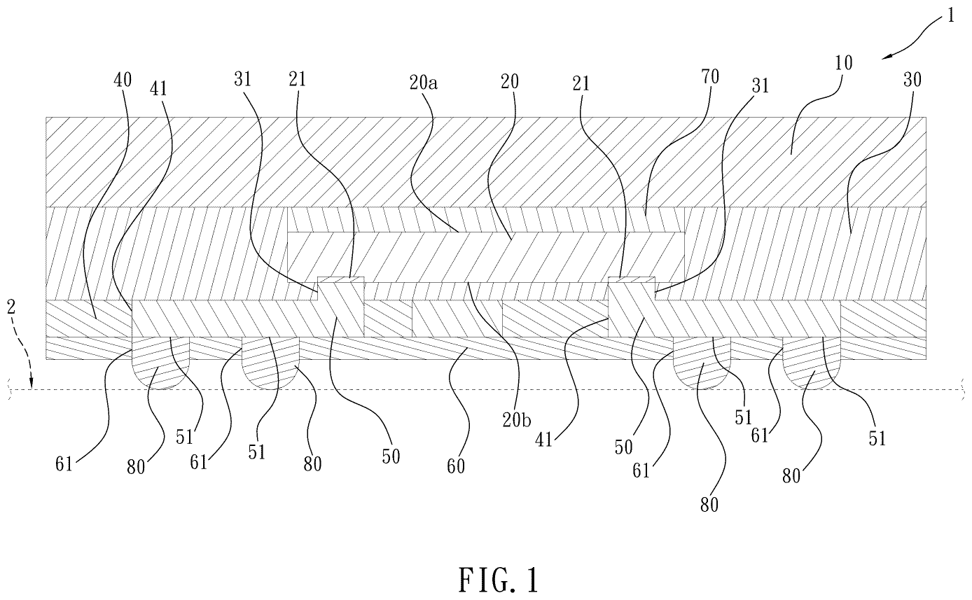

Refer to FIG. 1, a fan-out wafer-level packaging (FOWLP) unit 1 according to the present invention includes a substrate 10, a die 20, a first dielectric layer 30, a second dielectric layer 40, a plurality of conductive circuits 50, and an outer protective layer 60.

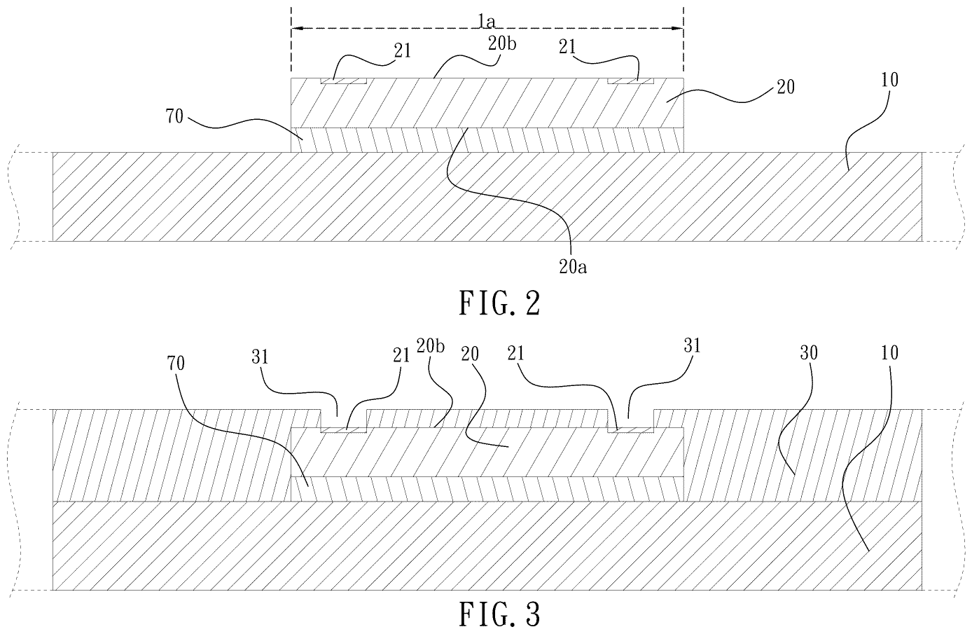

The substrate 10 includes silicon (Si) substrate, glass substrate, and ceramic substrate, but not limited, as shown in FIG. 2.

The die 20 is cut from a wafer and provided with a first surface 20a and a second surface 20b opposite to the first surface 20a. The first surface 20a of the die 20 is fixed on the substrate 10 while the second surface 20b of the die 20 is provided with a plurality of die pads 21. As shown in FIG. 2, an area just above the second surface 20b of the die 20 is defined as a chip area 1a. In the embodiment shown in FIG. 2, the number of the die pads 21 on the die 20 is two and this is only an example, not intended to limit the present invention.

Refer to FIG. 3, the first dielectric layer 30 is mounted to the substrate 10 and the second surface 20b of the die 20 and provided with a plurality of first slots 31 extending in a horizontal direction. The respective die pads 21 of the die 20 are exposed through the respective first slots 31, as shown in FIG. 3.

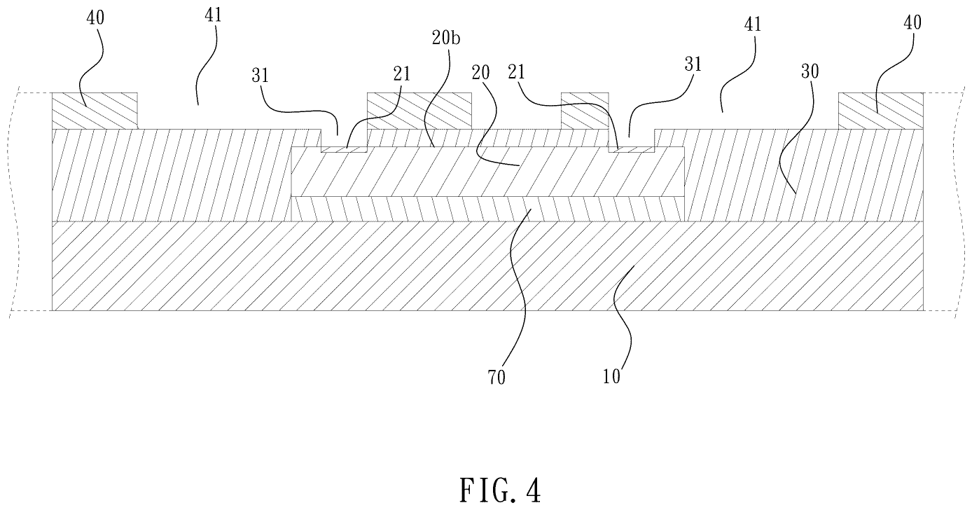

The second dielectric layer 40 is disposed over the first dielectric layer 30 and provided with a plurality of second slots 41 extending in a horizontal direction. The respective second slots 41 are communicating with the respective first slots 31, as shown in FIG. 4.

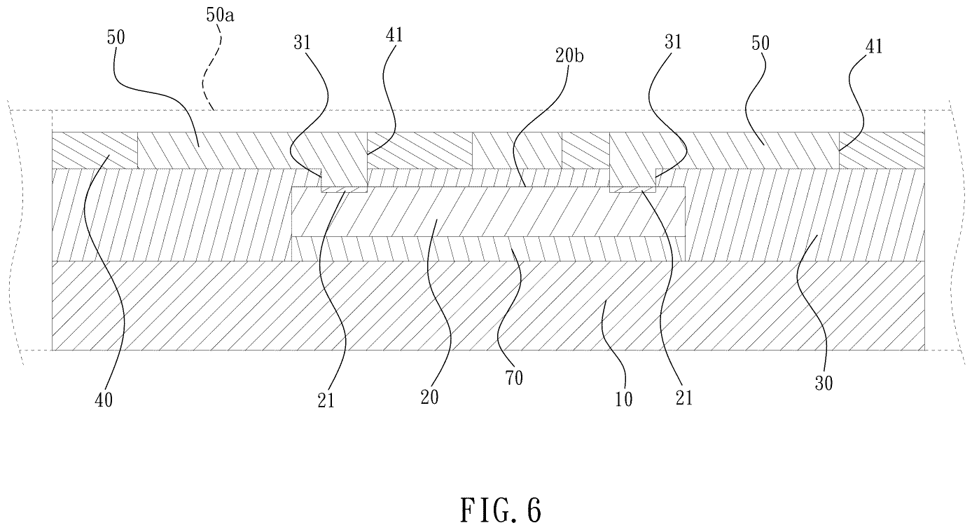

The respective conductive circuits 50 are formed by a metal paste 50a filled in the respective first slots 31 and the respective second slots 41. As shown in FIG. 6, the respective conductive circuits 50 are electrically connected with the respective die pads 21 of the die 20. The metal paste 50a includes, but not limited to silver paste, nano-scale silver paste, copper paste, and nano-scale copper paste. The nano-scale silver paste has features of low cost, high conductivity, and ability to be sintered at low temperature. The nano-scale silver paste is a common material available now and no more detailed description is given.

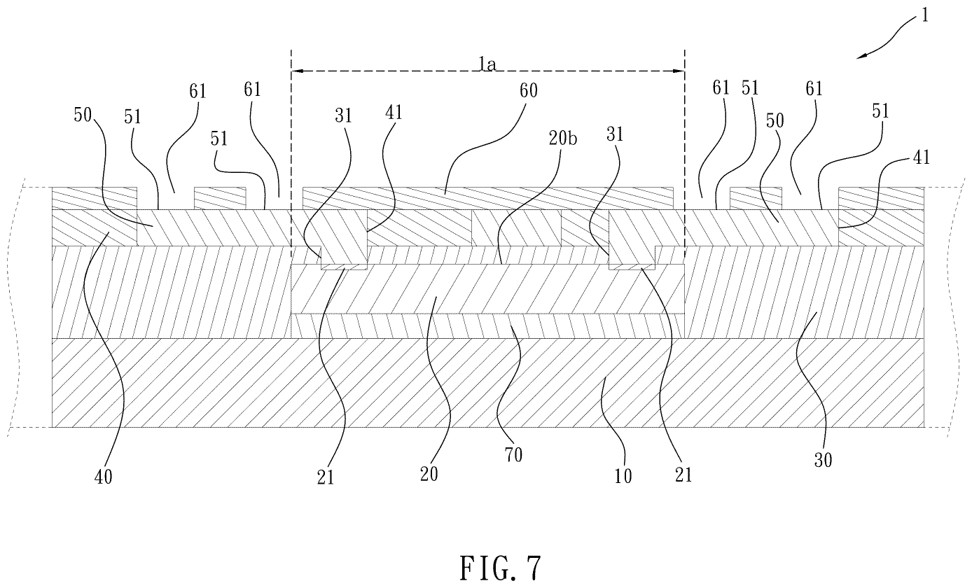

The outer protective layer 60 is arranged over the second dielectric layer 40 and provided with a plurality of openings 61. At least one of the openings 61 is located around the chip area 1a on the second surface 20b of the die 20, as shown in FIG. 7. Each of the conductive circuits 50 is exposed through the corresponding opening 61 and forming a bonding pad 51 in the corresponding opening 61, as shown in FIG. 7. In the embodiment shown in FIG. 7, there are four openings 61 in the outer protective layer 60. This is only an example, not intended to limit the present invention.

The die 20 is electrically connected to the outside through the respective die pads 21, the respective conductive circuits 50, and the respective bonding pads 51 around the chip area 1a on the second surface 20b of the die 20 in turn. Thereby the fan-out wafer-level packaging (FOWLP) unit 1 is formed, as shown in FIG. 7.

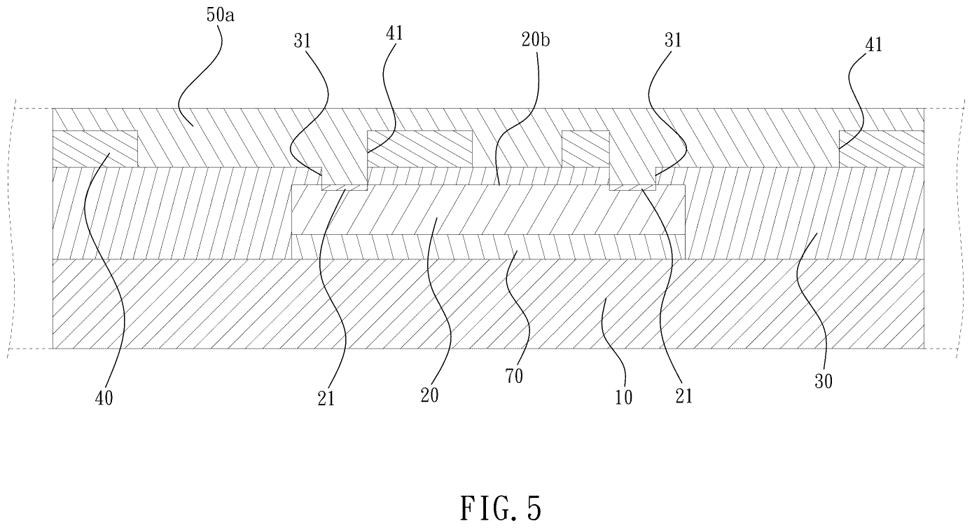

A method of manufacturing the fan-out wafer-level packaging (FOWLP) unit 1 according to the present invention includes the following steps.
Step S1: providing a substrate 10, as shown in FIG. 2.
Step S2: fixing and arranging a plurality of dies 20 cut from at least one wafer on the substrate 10 and the dies 20 are spaced apart from one another, as shown in FIG. 2. Take one of the dies 20 disposed on the substrate 10 in FIG. 2 as an example, not intend to limit the present invention. Each of the dies 20 includes a first surface 20a and a second surface 20b opposite to the first surface 20a. The first surface 20a of the die 20 is arranged at the substrate 10 while the second surface 20b of the die 20 is provided with a plurality of die pads 21. An area above/over the second surface 20b is defined as a chip area 1a, as shown in FIG. 2.
Step S3: paving a first dielectric layer 30 over the substrate 10 and the second surface 20b of the die 20, as shown in FIG. 3.
Step S4: forming a plurality of first slots 31 extending horizontally on the first dielectric layer 30 and exposing the respective die pads 21 of the respective dies 20 through the respective first slots 31, as shown in FIG. 3.
Step S5: paving/arranging a second dielectric layer 40 over the first dielectric layer 30, as shown in FIG. 4.
Step S6: forming a plurality of second slots 41 extending horizontally on the second dielectric layer 40 and the second slots 41 communicating with the first slots 31 correspondingly, as shown in FIG. 4.
Step S7: filling a metal paste 50a into the respective first slots 31 and the respective second slots 41 and a level of the metal paste 50a is higher than a surface of the second dielectric layer 40; this means the respective first slots 31 and the respective second slots 41 are completely filled with the metal paste 50a, as shown in FIG. 5.
Step S8: grinding the metal paste 50a with the level higher than the surface of the second dielectric layer 40 to make a surface of the metal paste 50a flush with the surface of the second dielectric layer 40 and form a plurality of conductive circuits 50, as shown in FIG. 6.
Step S9: covering the second dielectric layer 40 with an outer protective layer 60, as shown in FIG. 7.
Step S10: forming a plurality of openings 61 on the outer protective layer 60 and at least one of the openings 61 is formed around the chip area 1a on the second surface 20b of the die 20 so that each of the respective conductive circuits 50 is exposed through the corresponding opening 61 and forming a bonding pad 51 in the corresponding opening 61, as shown in FIG. 7.
Step S11: performing cutting to form a plurality of fan-out wafer-level packaging (FOWLP) units 1, as shown in FIG. 7. In the embodiment shown in FIG. 7, one FOWLP unit 1 is taken as an example, not intended to limit the present invention.

The steps S3-S10 during a process of the method of manufacturing the fan-out wafer-level packaging (FOWLP) unit 1 are considered as key steps of manufacturing the redistribution layer (RDL) of the FOWLP unit 1. The steps S4 is forming a plurality of first slots 31 extending horizontally on the first dielectric layer 30. The steps S6 is forming a plurality of second slots 41 extending horizontally on the second dielectric layer 40. The steps S7 is filling a metal paste 50a into the respective first slots 31 and the respective second slots 41. The steps S8 is grinding the metal paste 50a with the level higher than the surface of the second dielectric layer 40 to make a surface of the metal paste 50a flush with the surface of the second dielectric layer 40. The steps S4-S8 are easy to be implemented precisely so that the manufacturing process is simplified and the respective conductive circuits 50 in the RDL have electrical extension in the XY plane and interconnections. At the same time, the FOWLP unit 1 manufactured still has slim size and light weight to some degree.

Refer to FIG. 2, the first surface 20a of the die 20 is arranged and fixed on the substrate 10 by a die attach film (DAF) 70, but not limited.

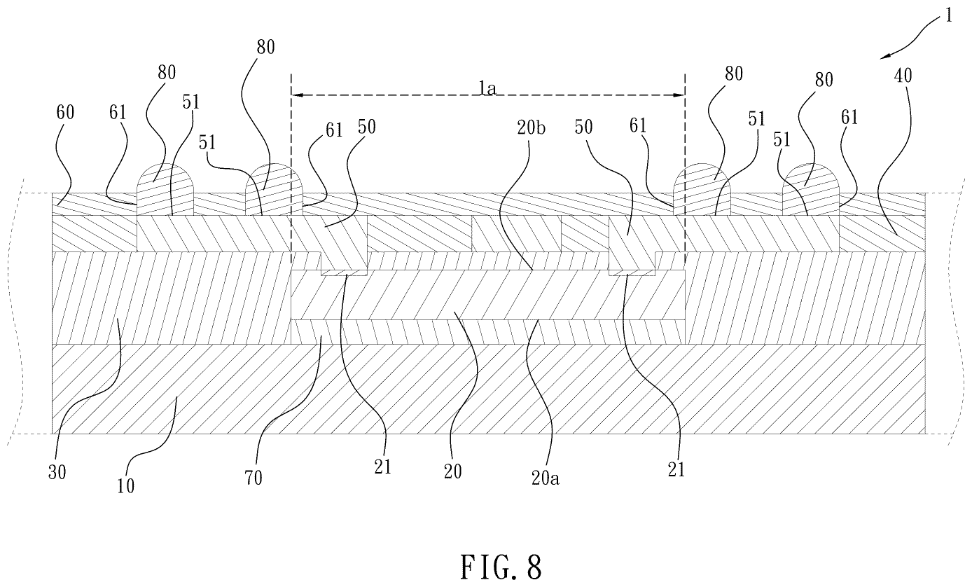

Refer to FIG. 8, each of the openings 61 is provided with a solder ball 80 which is electrically connected with the bonding pad 51 in the opening 61.

Refer to FIG. 1, the FOWLP unit 1 can be electrically connected and disposed on a printed circuit board (PCB) 2 by the respective solder balls

80, but not limited.

Compared with the FOWLP unit available now, the FOWLP unit 1 of the present invention has the following advantages.
(1) Compared with manufacturing techniques of FOWLP units available now, the steps S3-S10 of the present method of manufacturing the FOWLP unit 1 are simplified and easily-implemented steps. By the above manufacturing process, the respective conductive circuits in the RDL can maintain a certain degree of compact design in the state of having electrical extension in the XY plane and interconnections. This is especially beneficial to reducing the thickness of the package unit. Therefore, the manufacturing process of the present invention is not only more simplified with reduced cost, but also improving use efficiency and reliability of the FOWLP unit 1.
(2) The present method of forming the respective conductive circuits 50 is first filling the metal paste 50a into the into the respective first slots 31 and the respective second slots 41 and the level of the metal paste 50a is higher than the surface of the second dielectric layer 40, as shown in FIG. 5. Then grinding the metal paste 50a with the level higher than the surface of the second dielectric layer 40 to make the surface of the metal paste 50a flush with the surface of the second dielectric layer 40 and form a plurality of conductive circuits 50a, as shown in FIG. 6. Therefore, the present invention can solve the problems of the fan-out level packaging technology available now generated during manufacturing of the respective conductive circuits including higher manufacturing cost and less environmental benefit.

1. A fan-out wafer-level packaging (FOWLP) unit comprising:
a substrate;
a die cut from a wafer and provided with a first surface and a second surface arranged opposite to each other; the first surface of the die fixed on the substrate and the second surface of the die provided with a plurality of die pads; an area above the second surface of the die being defined as a chip area;
a first dielectric layer mounted to the substrate and the second surface of the die and provided with a plurality of first slots extending in a horizontal direction; wherein each of the die pads of the die is exposed through the corresponding first slot;
a second dielectric layer disposed over the first dielectric layer and provided with a plurality of second slots extending in a horizontal direction; the second slots communicating with the first slots correspondingly;
a plurality of conductive circuits formed by a metal paste filled in the respective first slots and the respective second slots; the respective conductive circuits electrically connected with the respective die pads of the die; and
an outer protective layer arranged over the second dielectric layer and provided with a plurality of openings; at least one of the openings located around the chip area on the second surface of the die; wherein each of the conductive circuits is exposed through the corresponding opening and forming a bonding pad in the opening;
wherein the die is electrically connected to the outside through the respective die pads, the respective conductive circuits, and the respective bonding pads around the chip area on the second surface of the die; thereby the FOWLP unit is formed;
wherein a method of manufacturing the fan-out wafer-level packaging (FOWLP) unit comprising the steps of:
Step S1: providing a substrate;
Step S2: arranging a plurality of dies cut from at least one wafer on the substrate and the dies are spaced apart from one another; wherein each of the dies includes a first surface and a second surface opposite to the first surface; the first surface of the die is arranged at the substrate while the second surface of the die is provided with a plurality of die pads and an area above the second surface of the die is defined as a chip area;
Step S3: paving a first dielectric layer over the substrate and the second surface of the respective dies;
Step S4: forming a plurality of first slots extending horizontally on the first dielectric layer and exposing the respective die pads of the respective dies through the respective first slots;
Step S5: covering the first dielectric layer with a second dielectric layer;
Step S6: forming a plurality of second slots extending horizontally on the second dielectric layer and the respective second slots communicating with the respective first slots;
Step S7: filling a metal paste into the respective first slots and the respective second slots and a level of the metal paste is higher than a surface of the second dielectric layer;
Step S8: grinding the metal paste with the level higher than the surface of the second dielectric layer to make a surface of the metal paste flush with the surface of the second dielectric layer and form a plurality of conductive circuits;
Step S9: covering the second dielectric layer with an outer protective layer;
Step S10: forming a plurality of openings on the outer protective layer and at least one of the openings is formed around the chip area on the second surface of the die so that each of the conductive circuits is exposed through the corresponding opening and forming a bonding pad in the corresponding opening; and
Step S11: performing cutting to form a plurality of fan-out wafer-level packaging (FOWLP) units.

2. The fan-out wafer-level packaging (FOWLP) unit as claimed in claim 1, wherein the substrate is selected from the group consisting of silicon (Si) substrate, glass substrate, and ceramic substrate.

3. The fan-out wafer-level packaging (FOWLP) unit as claimed in claim 1, wherein the metal paste is selected from the group consisting of silver paste, nano-scale silver paste, copper paste, and nano-scale copper paste.

4. The fan-out wafer-level packaging (FOWLP) unit as claimed in claim 1, wherein the first surface of the die is arranged at the substrate by a die attach film (DAF).

5. The fan-out wafer-level packaging (FOWLP) unit as claimed in claim 1, wherein each of the openings is provided with a solder ball which is electrically connected with the bonding pad in the opening.

6. The fan-out wafer-level packaging (FOWLP) unit as claimed in claim 5, wherein the fan-out wafer-level packaging (FOWLP) unit is electrically connected to and disposed on a printed circuit board (PCB) by the solder balls.
